(19) United States
(12) Patent Application Publication
(10) Pub. No.: US 2007/0042820 A1
(43) Pub. Date: Feb. 22, 2007

(54) Garter holder for small electronic device about leg or thigh

(76) Inventor: Pamela Cloonan, Miami, FL (US)

Correspondence Address: STEVEN PINKERT, ESQ.;PINKERT LAW FIRM, P.A., STE 1528, 9130 S. DADELAND BLVD, MIAMI, FL, 33156, US

(21) Appl. No.: 11/506,225

(22) Filed: Aug. 18, 2006

Related U.S. Application Data
(60) Provisional application No. 60/709,987, filed on Aug. 19, 2005.

(51) Int. Cl. H05K 11/00; H04M 1/00

(52) U.S. Cl. 455/575.6; 455/344

(57) ABSTRACT

An electronic device holder of a garter-type design, to be worn for convenient access to the electronic device and as a fashion accessory. The invention comprises a leg strap, device support, and straps or a plate to hold down the device. In the preferred embodiment, the leg strap, a continuous piece of elastomeric material, is attached to a hard ring support or other support of polygonal or freeform shape and three elastomeric straps, one positioned vertically and the other two straps positioned to properly secure the electronic device. In some embodiments the support is a plate with slots or holes for attachment to the leg strap and to accommodate the electronic device. All embodiments may also contain one or more thin swatches of fabric positioned either in front or in back of the electronic device to accommodate small I.D.'s, credit cards, and/or dollar bills.

### CROSS-REFERENCE TO RELATED APPLICATIONS

This application claims the benefit of U.S. Provisional Application No. 60/709,987, filed Aug. 19, 2005. The entire disclosure of this prior application is hereby incorporated by reference.

### STATEMENT REGARDING FEDERALLY SPONSORED RESEARCH OR DEVELOPMENT

This invention has been created without the sponsorship or funding of any federally sponsored research or development program.

### FIELD OF THE INVENTION

The present invention relates generally to the field of carrying devices for small personal electronics. For example, the invention relates specifically to a garter-type holder to be worn on the legs or thigh of an individual to securely and discreetly accommodate any personal electronic devices the user may select.

### BACKGROUND OF THE INVENTION

The present invention relates to a device that is designed in such a way as to provide stability for insertion, removal, and carrying of a small electronic device on a single strap on the leg or thigh. The present invention is designed to secure and hold the small electronic device in place providing a hands free holder attached to a single strap, the strap being attached to the body. For purposes of this invention, small electronic devices include, but are not limited to, cellular telephones, MP3 players, Blackberries, iPods, PDAs, Palm Pilots, pagers, walkie-talkie radios and other small handheld electronic devices. The present invention provides a practical and fashionable way of carrying small electronic devices to the beach, outdoor concerts, nightclubs, and other venues where bulky bags are not ideal, as well as for everyday use.

Many different small electronic device holders for use on the body are known. The most popular of these holders are fastened to the belt or waist of a person's clothing. This traditional type of small electronic device holder is cumbersome and does not always conform to the fashion trends of young girls and women, but is more masculine in design and function (like a holster on the belt). Further, it is not always desirable that the small electronic device be attached to the clothing and thus is usually carried in the hands, a practice which is inconvenient and increases the likelihood that it will be misplaced, lost, or damaged.

This present invention came to life while the inventor was sitting at a casual restaurant and observed two young ladies (early twenties) come into the restaurant attired in beachwear, namely sarongs and bikini tops, without purses but carrying cellular telephones in their hands. Throughout the remainder of her meal, the inventor noticed more young women come and go, but they all had the same thing in common, they were fashionably dressed with no purses and carried their cellular telephones in their hands. In one instance, the inventor observed a young woman get up from her table to empty her tray with her cellular telephone in hand. The inventor watched as the young woman rested the cellular telephone on top of the trash bin and emptied her tray, while speaking to a friend. “I hope she doesn't forget to pick up her phone,” was the thought that came to the inventor's mind.

Based on these encounters along with other repeatedly similar scenes, it became apparent that many women in the age group from teens to late 30's all had some things in common: (1) they are rarely without their cellular telephones; (2) they do not always carry purses; and (3) they do not wear belt type clips for the cellular telephones (not attractive and too masculine), but instead carry their cellular telephones in their hands. This realization gave birth to the idea that women need an attractive, fashionable (even sexy) way of wearing their cellular telephones and the like small electronic devices.

The present invention provides a holder for cellular telephones and the like small electronic devices in a “garter” type device. This present invention incorporates a garter with the capability of securing a small electronic device about the leg or thigh of a person with a single strap. The invention securely holds the small electronic device and permits easy removal and insertion of the device while the wearer is on the beach or elsewhere and simultaneously functioning as a piece of fashion wear or an “accessory”.

### SUMMARY OF THE INVENTION

It is an object of the present invention to provide a practical, yet attractive (sexy) and fashionable means for young girls and women to hold or carry cellular telephones and the like small electronic devices. This invention may be worn on the bare leg, under clothing such as a dress, or over clothing such as leggings or pants in a garter-like fashion to facilitate easy access and hassle free carrying.

The invention consists of a flat hard or semi-hard material that is approximately the length and width of the small electronic device attached to a single strap that secures the device to the leg or thigh. A flexible strap made of elastomeric material combined with other straps made of elastomeric or non-elastomeric material forms a pocket-like area in order to achieve both an attractive look (garter) and function. The pocket is not necessarily a completely enclosed pocket but may also consist of straps. Another embodiment of the present invention is also designed to secure I.D.'s and other cards either in front or in back of the small electronic device.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

In describing the invention, reference will at times be made to the accompanying drawings in which:

FIG. 1 is a diagram of the basic components of the preferred embodiment of the invention;

FIG. 2 is a diagram of the basic components of the preferred embodiment of the invention, illustrating its use with a small electronic device, specifically a cellular telephone;

FIG. 3 is a diagram of the preferred embodiment of the invention, illustrating the “garter” character of the invention as worn on a woman's thigh, and showing various perspectives of the invention;

FIG. 4 is a diagram giving a perspective view of the preferred embodiment of the invention with a small electronic device;

FIGS. 5 through 9 are color photos of the preferred embodiment of the invention as illustrated in FIGS. 1 through 4;

FIG. 10 is a color photo of the preferred embodiment of the invention as worn as a garter on bare legs by a woman wearing a swimsuit;

FIGS. 11 through 13 are color photos of the preferred embodiment of the invention as worn over pants or blue jeans;

FIG. 14 is a color photo of the preferred embodiment of the invention, illustrating faux fur finish;

FIG. 15 is a color photo of the preferred embodiment of the invention highlighting its functionality as a fashion accessory;

FIG. 16 is a color photo of the preferred embodiment of the invention as worn as a garter on bare legs by a woman in a dress;

FIG. 17 is a diagram of the rigid plastic pocket embodiment of the present invention;

FIG. 18 is a diagram of the rigid plastic plate with edge extensions embodiment of the present invention, illustrating its use with a small electronic device, specifically a cellular telephone.

### DETAILED DESCRIPTION OF INVENTION

Before the subject invention is described further, it is to be understood that the invention is not limited to the particular embodiments of the invention described below, as variations of the particular embodiments may be made and still fall within the scope of the invention. It is also to be understood that the terminology employed is for the purpose of describing particular embodiments, and is not intended to be limiting.

In this specification, the singular forms “a,” “an” and “the” include plural reference unless the context clearly dictates otherwise. Unless defined otherwise, all technical and scientific terms used herein have the same meaning as commonly understood to one of ordinary skill in the art to which this invention belongs.

The details of one or more embodiments of the invention are set forth in the accompanying drawings and the description below. Other features, objects, and advantages of the invention will be apparent from the description and drawings, and from the claims.

### DESCRIPTION OF THE PREFERRED EMBODIMENT

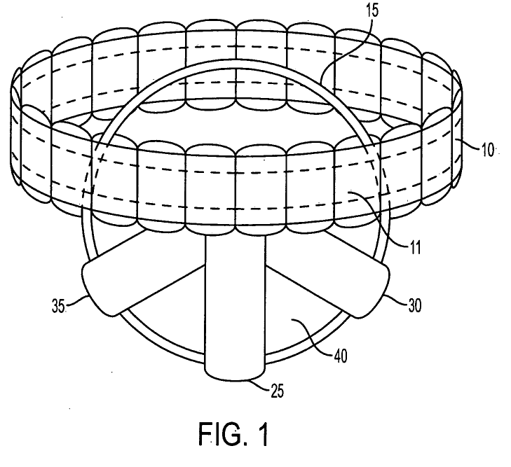

With reference to FIG. 1, the preferred embodiment of the invention is comprised of three basic components. The first component is a single leg strap 10 consisting of elastic only or elastic attached to fabric which may be three-fourths inch to one and a half inches in width forming a garter type device. The second component is a support 15 and as shown in FIG. 1, is comprised of a hard ring 15 approximately three inches in diameter and three millimeters in width/thickness. The third component consists of three smaller electronic device straps 25, 30, 35. The hard ring 15 is attached in two places to the inner side of the single leg strap 10 and the portion that lies between the points of attachment to the hard ring provides an additional support band 11 for the small electronic device. When the small electronic device is inserted (in front of the ring), the additional support band 11 stretches across the front and sides of the small electronic device pressing and holding the small electronic device against the hard ring 15, providing lateral support.

The three electronic device straps 25, 30, and 35 attach at one end to the hard ring as shown in FIG. 1 and at their other end attach together to the center of the additional support band 11 of the single leg strap 10. One electronic device strap 25 is vertically oriented while the other two straps 30 and 35 are oriented to properly secure and support the electronic device. When the small electronic device is inserted (in front of the hard ring 15), the electronic device straps 25, 30 and 35 stretch across the front and sides of the small electronic device pressing and holding the small electronic device against the hard ring 15, further providing lateral support and preventing the small electronic device from slipping out of the bottom of the invention.

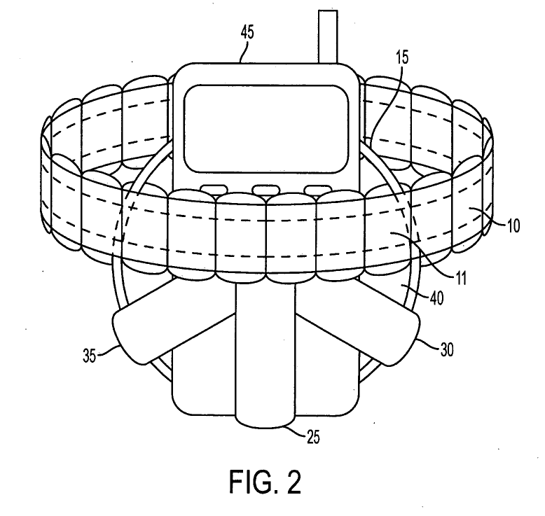

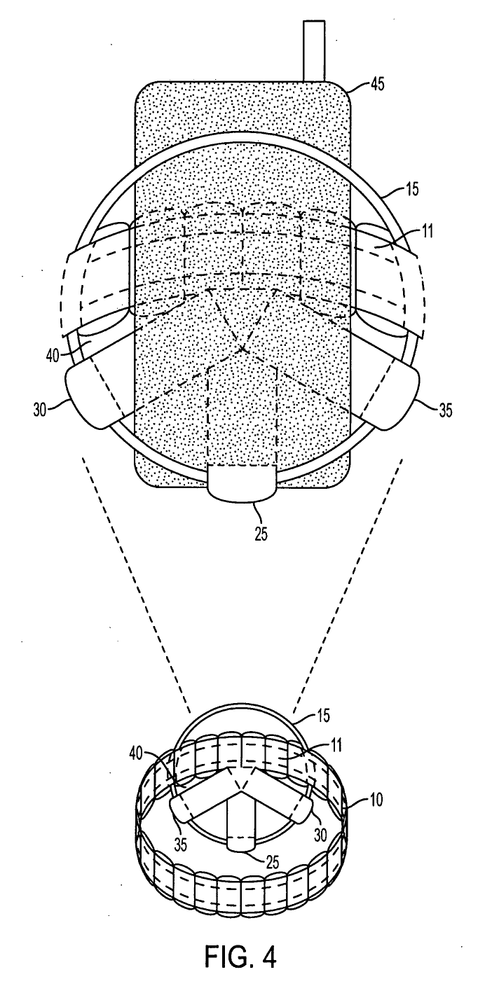

A space or pocket like area 40 is formed on one side by the hard ring 15, the additional support band 11, and by the three electronic device straps 25, 30, and 35. The small electronic device, a cellular telephone 45 as shown in FIG. 2, is inserted between the hard ring 15 and the additional support band 11 and electronic device straps 25, 30, and 35 such that the hard ring 15 and the additional support band 11 supports the back of the small electronic device, while the electronic device straps 25, 30, and 35 support the bottom, front, and sides of the small electronic device, as illustrated in FIG. 4.

The top of the small electronic device remains uncovered to facilitate easy removal and insertion of the small electronic device. Note, in other embodiments a strap, clip, or other piece of material may extend over the top of the device and be removed, opened, or pulled out of the way to access the small electronic device.

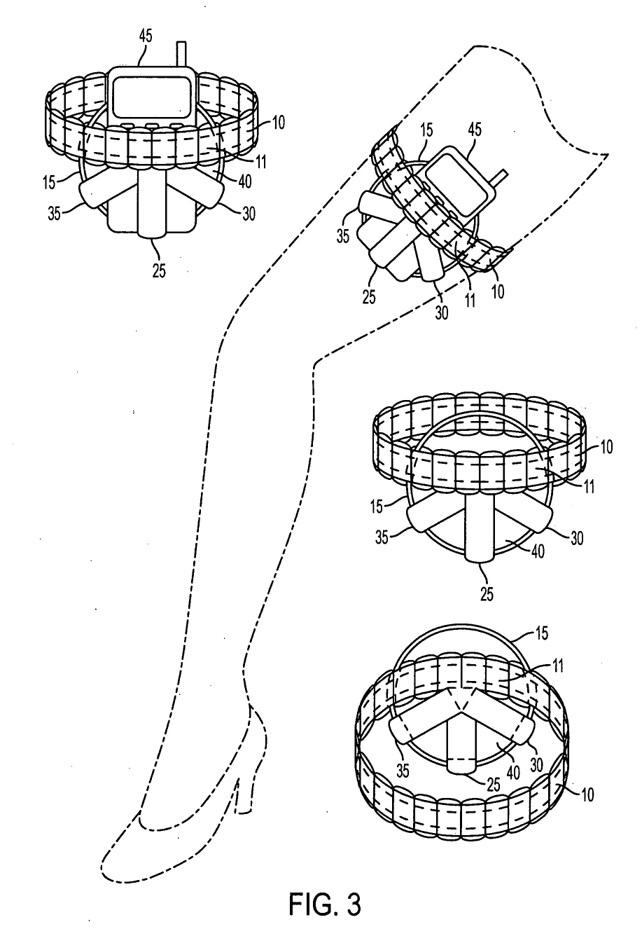

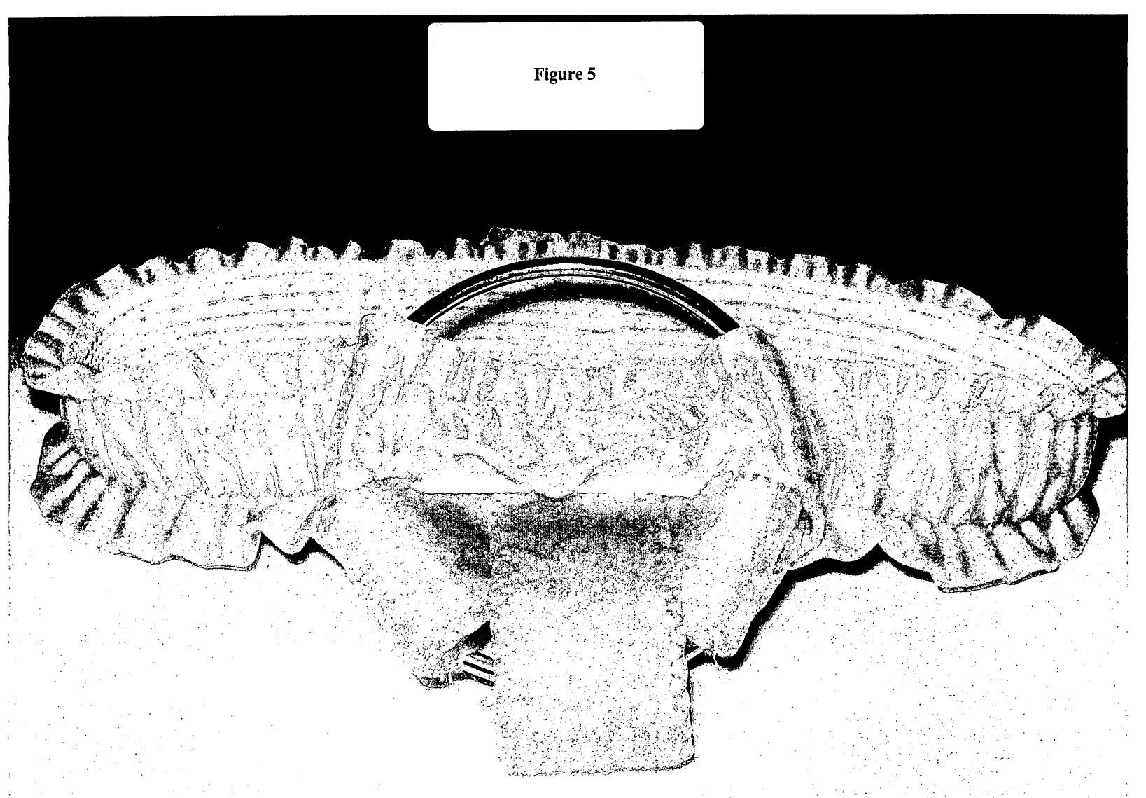

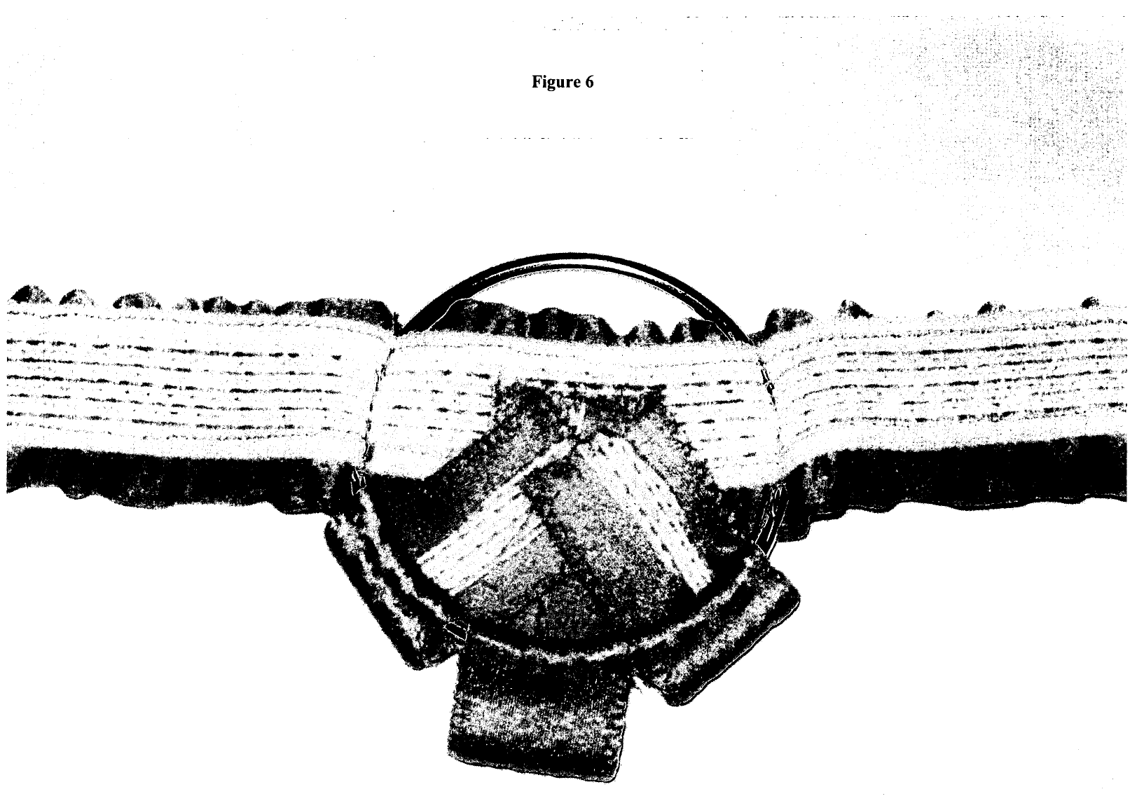

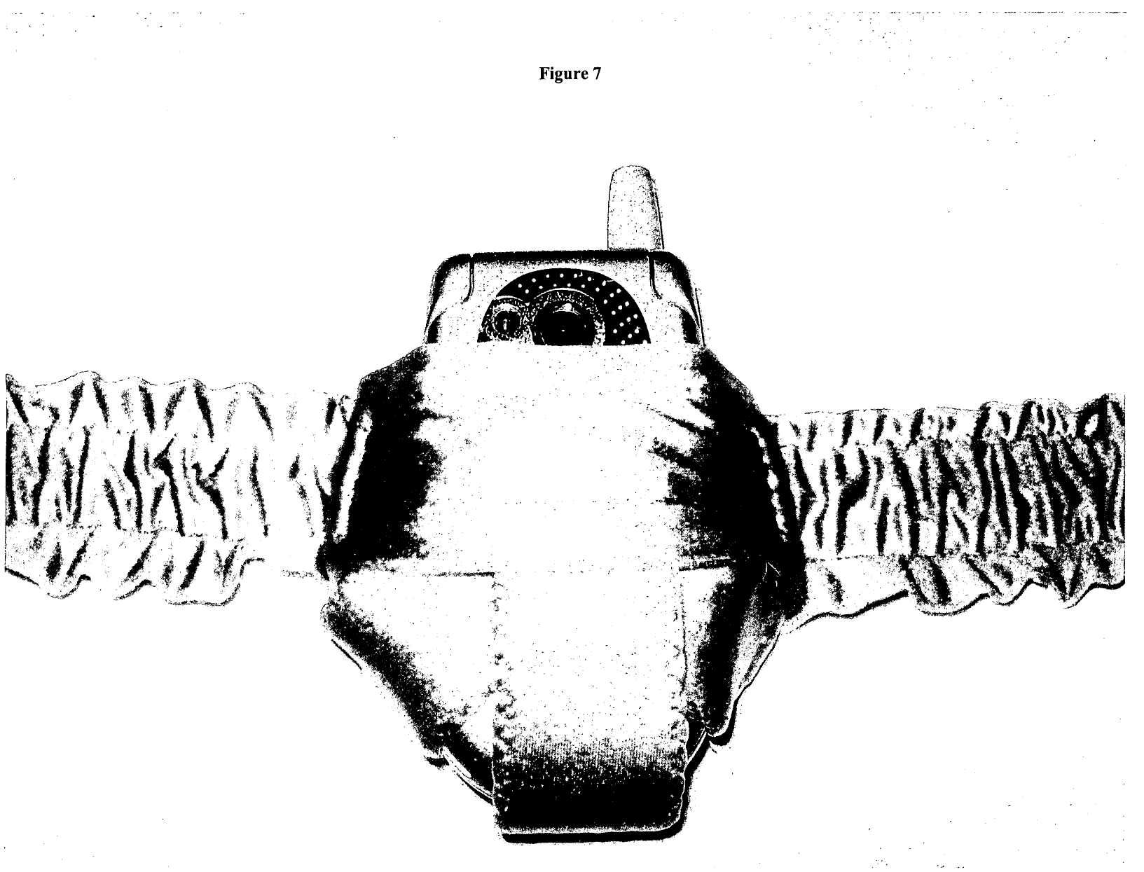

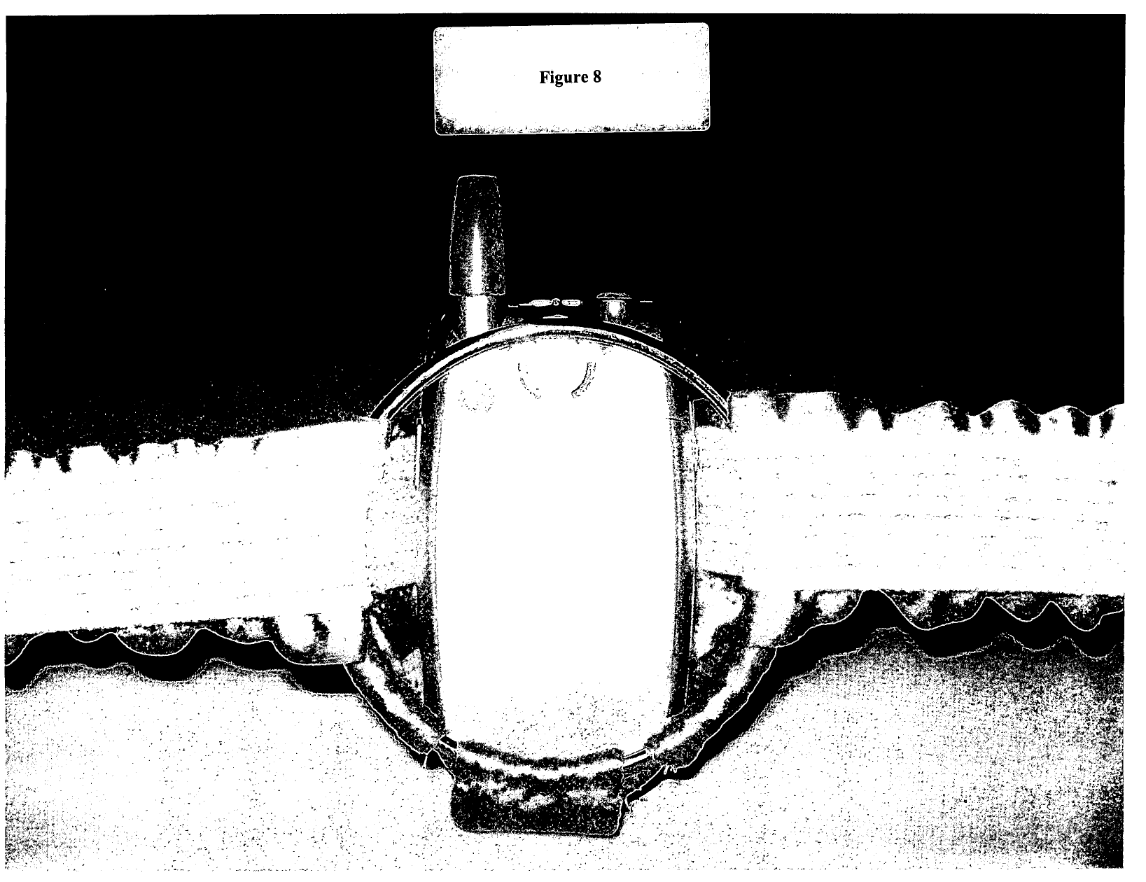

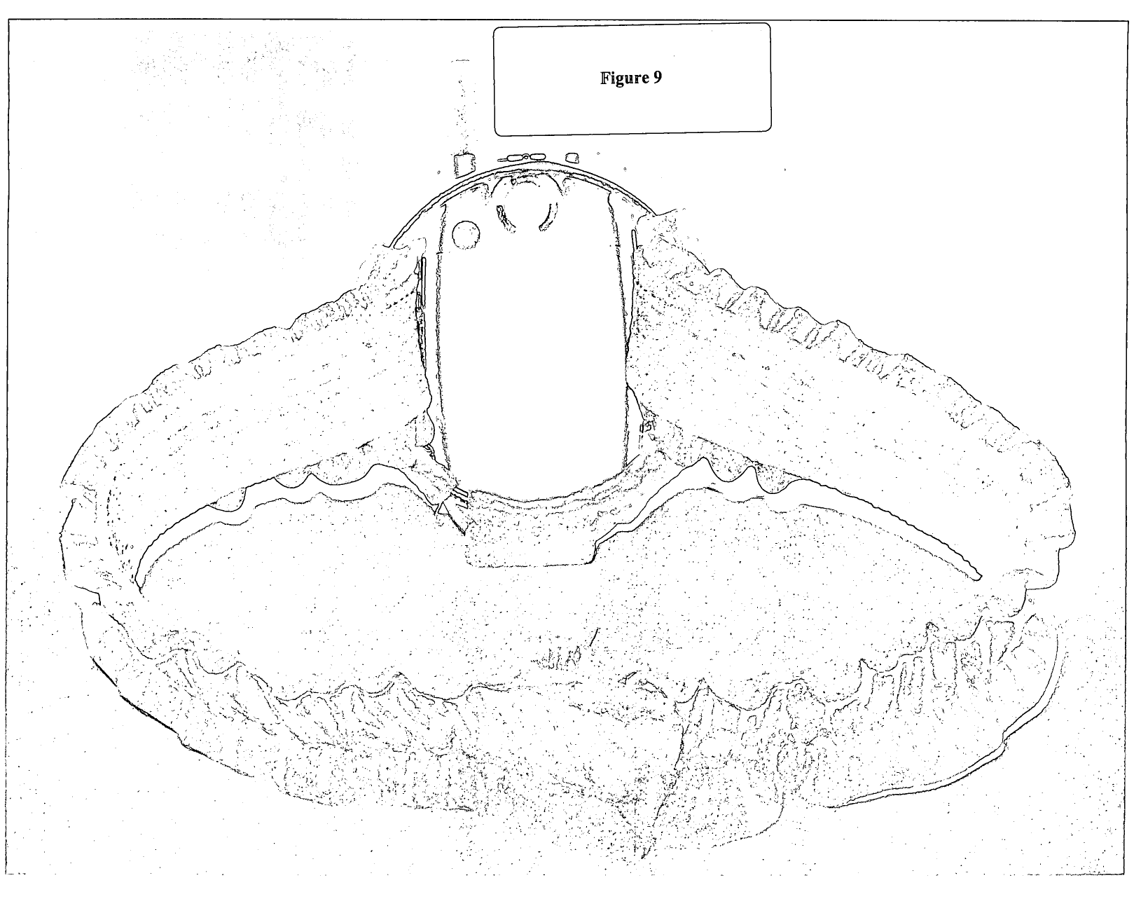

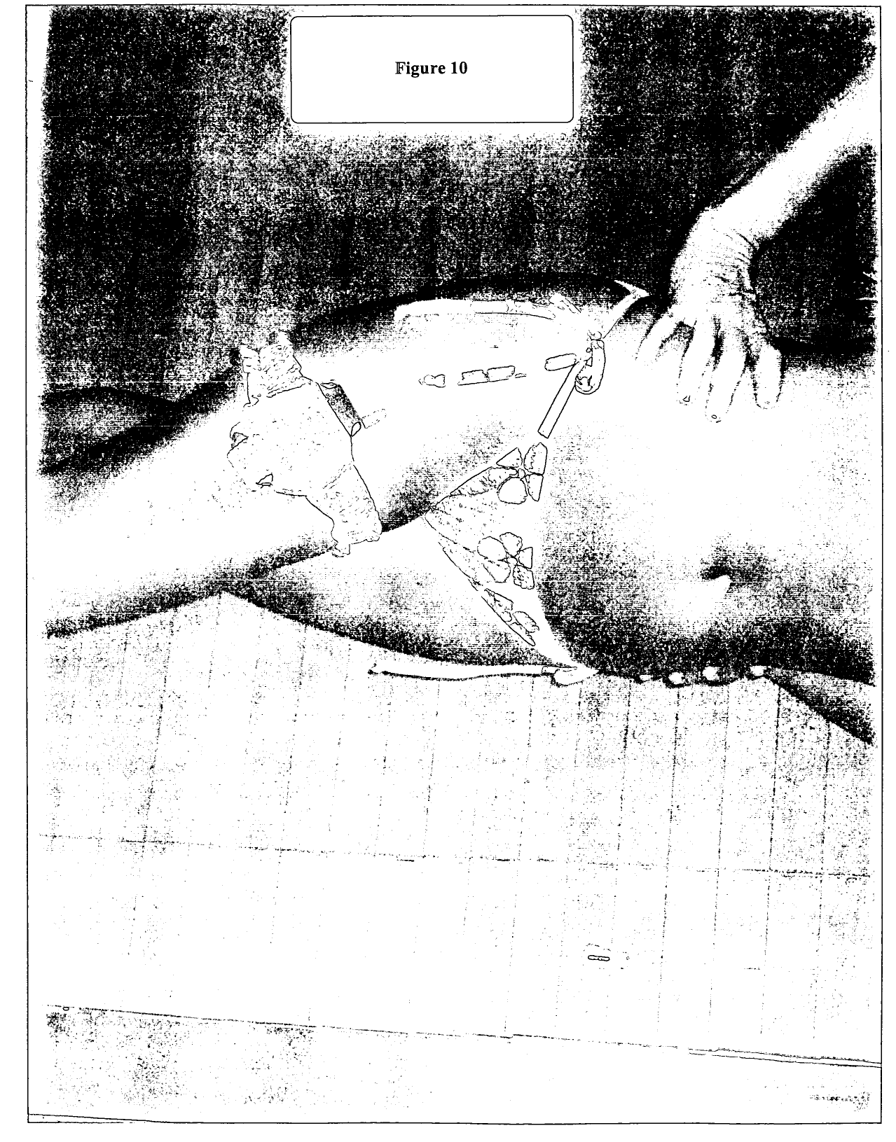

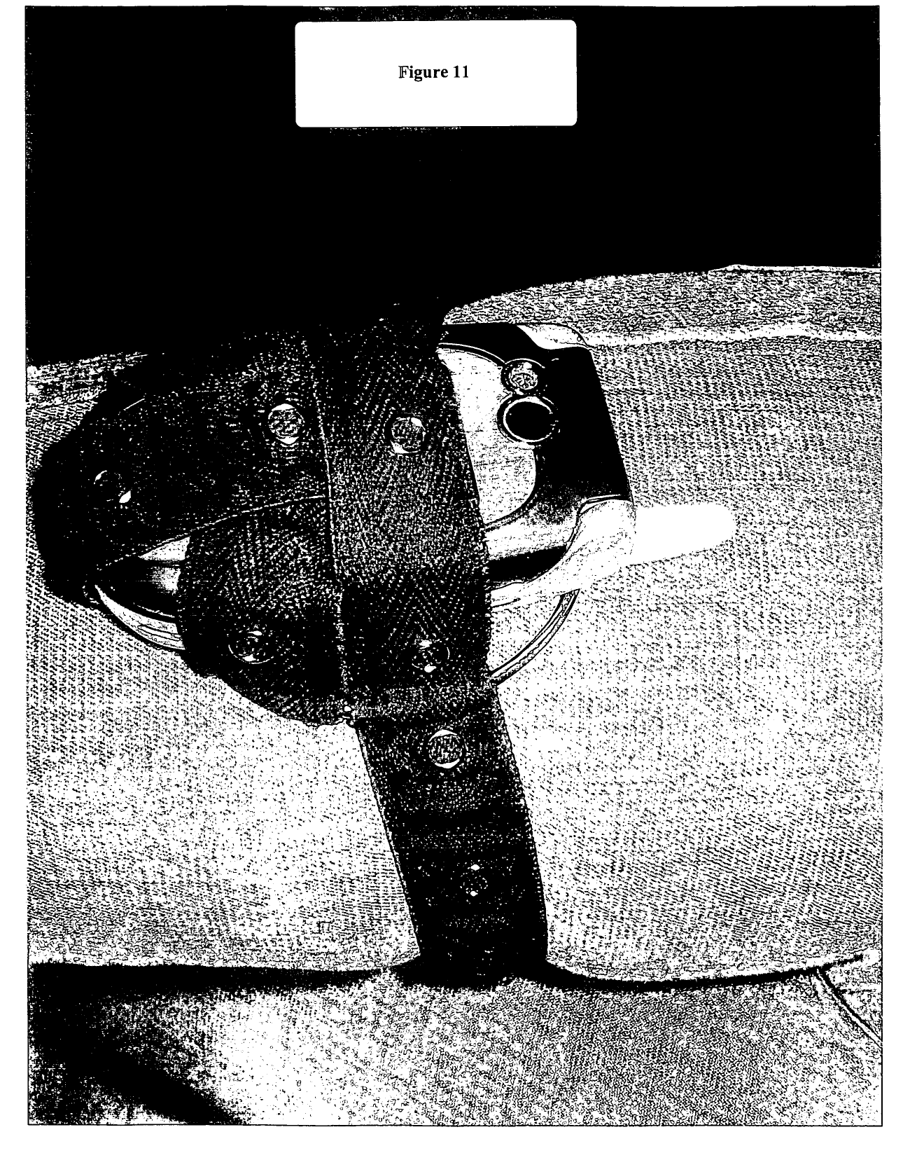

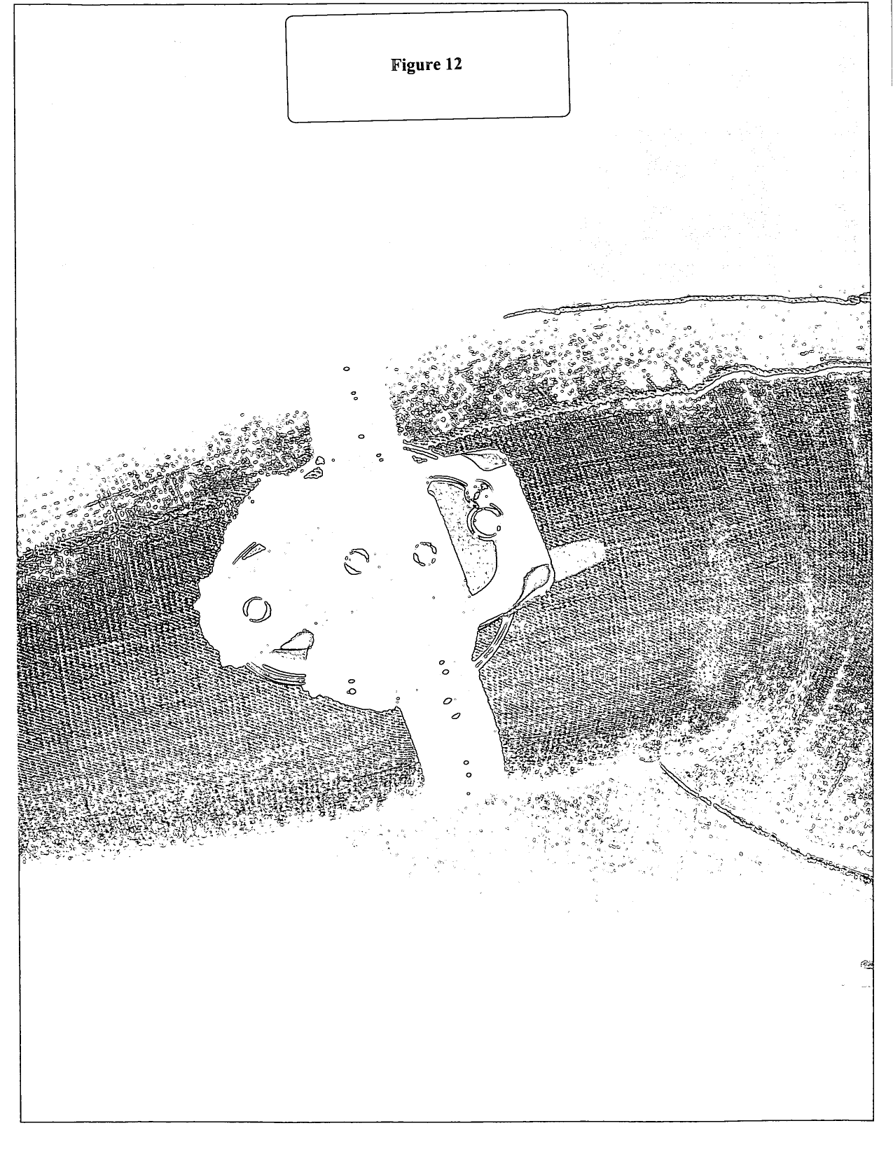

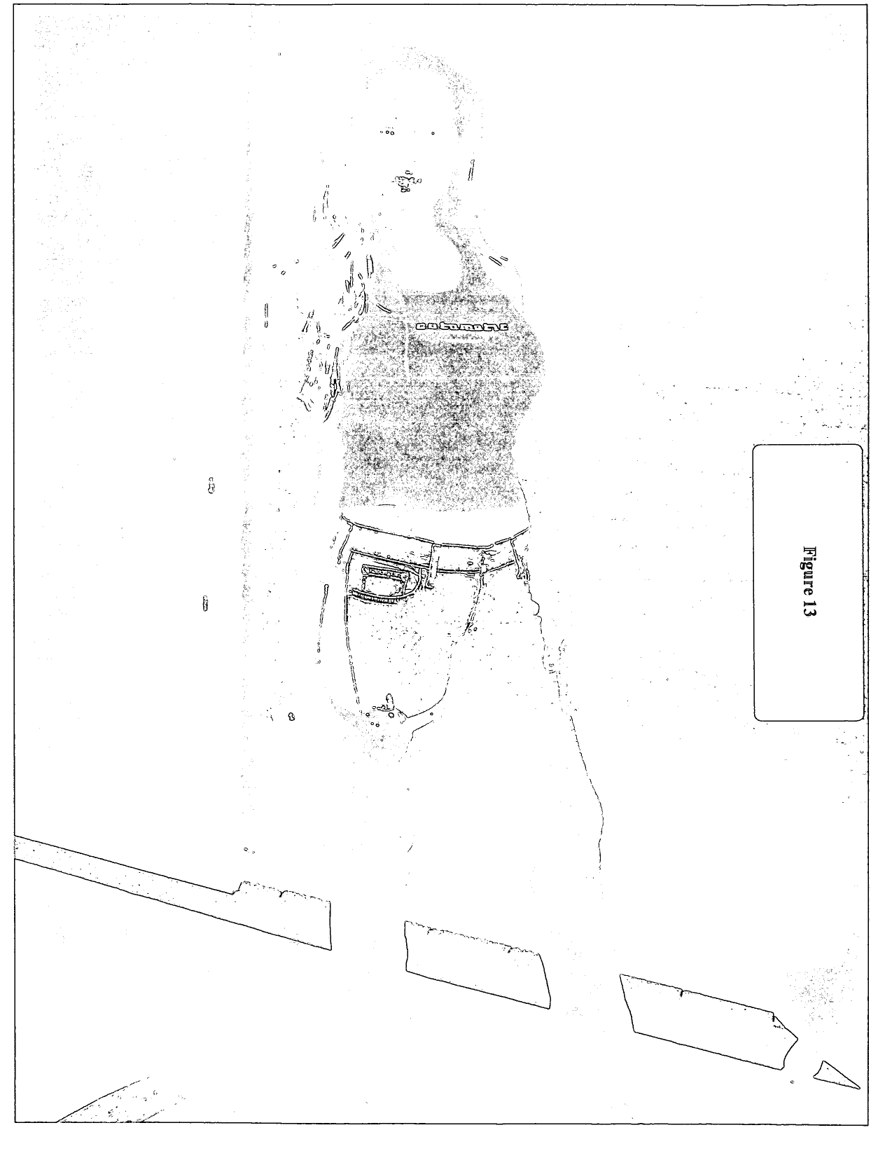

The preferred embodiment of the invention is worn like a garter on the thigh or leg with the fabric covering the straps 10 (and 11), 25, 30, and 35 facing away from the thigh or leg as shown in FIG. 3 and see also FIGS. 5-16.

### DESCRIPTION OF ALTERNATE EMBODIMENTS

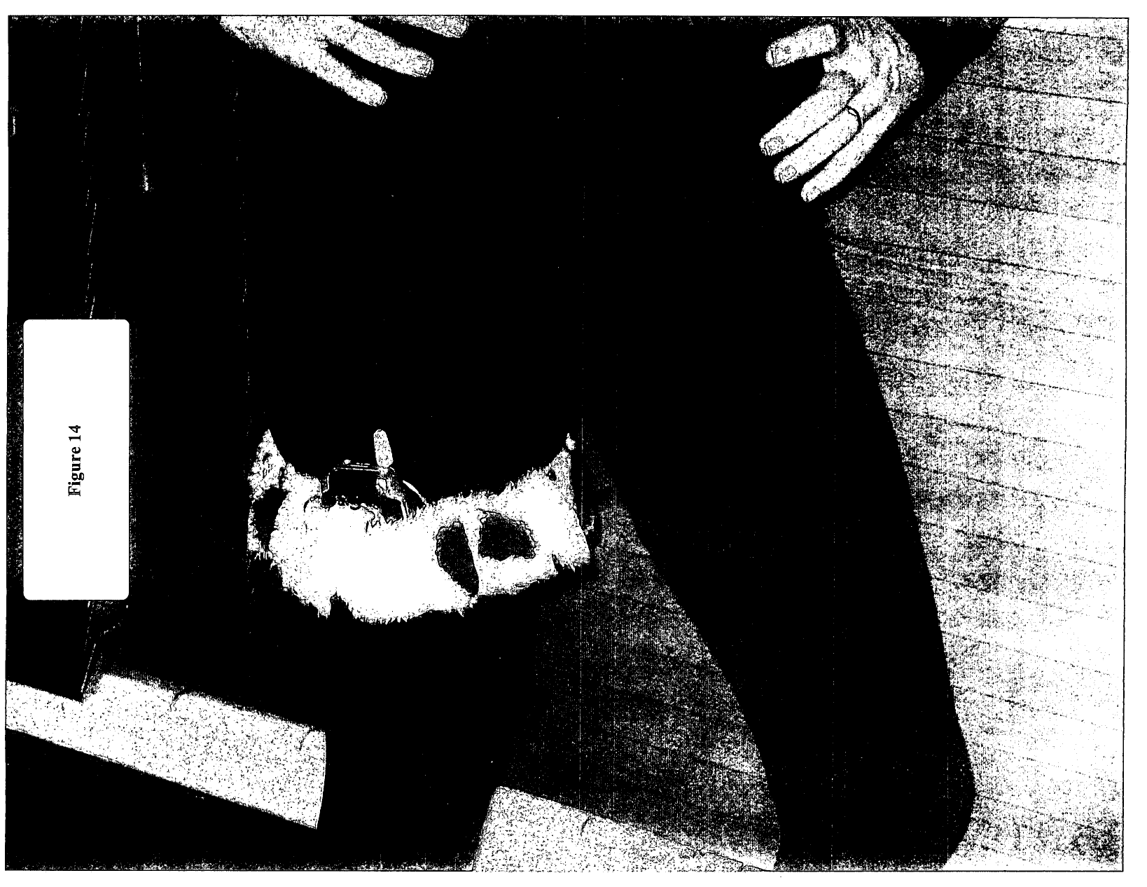

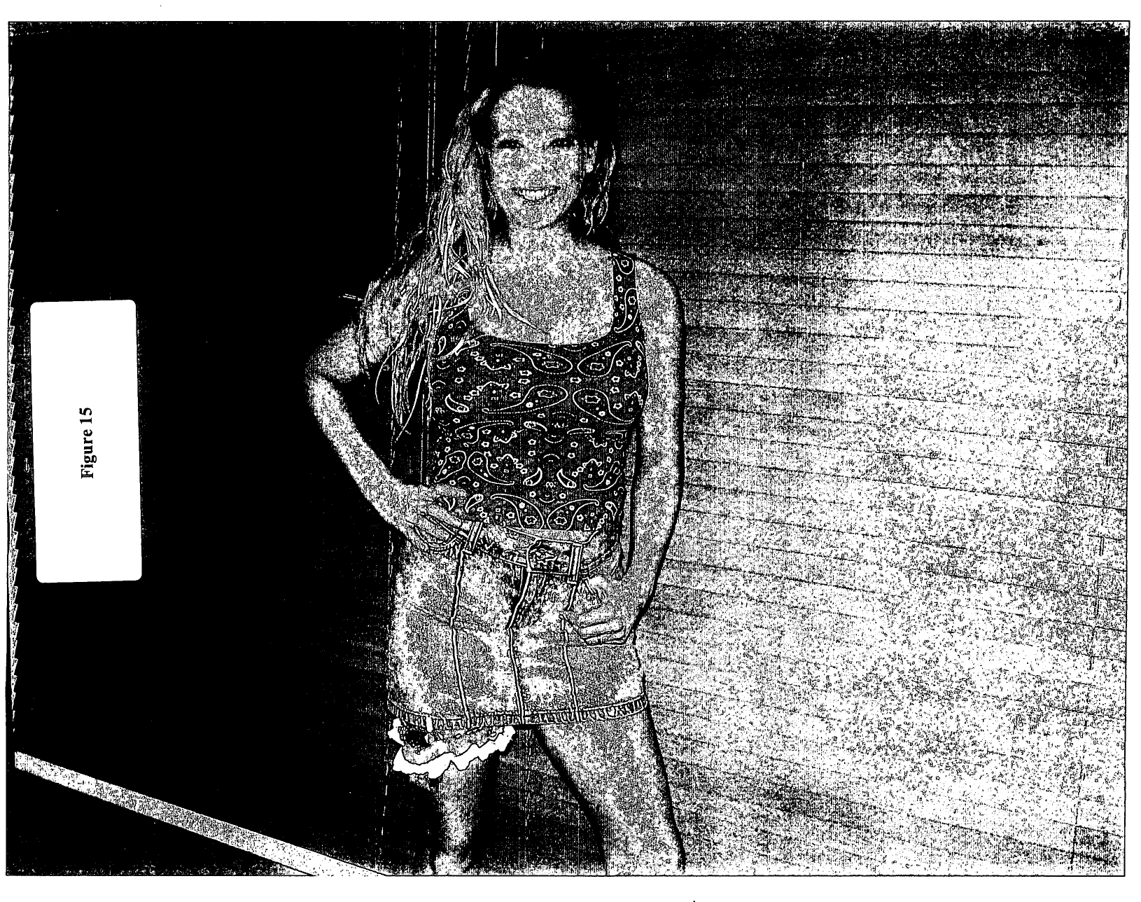

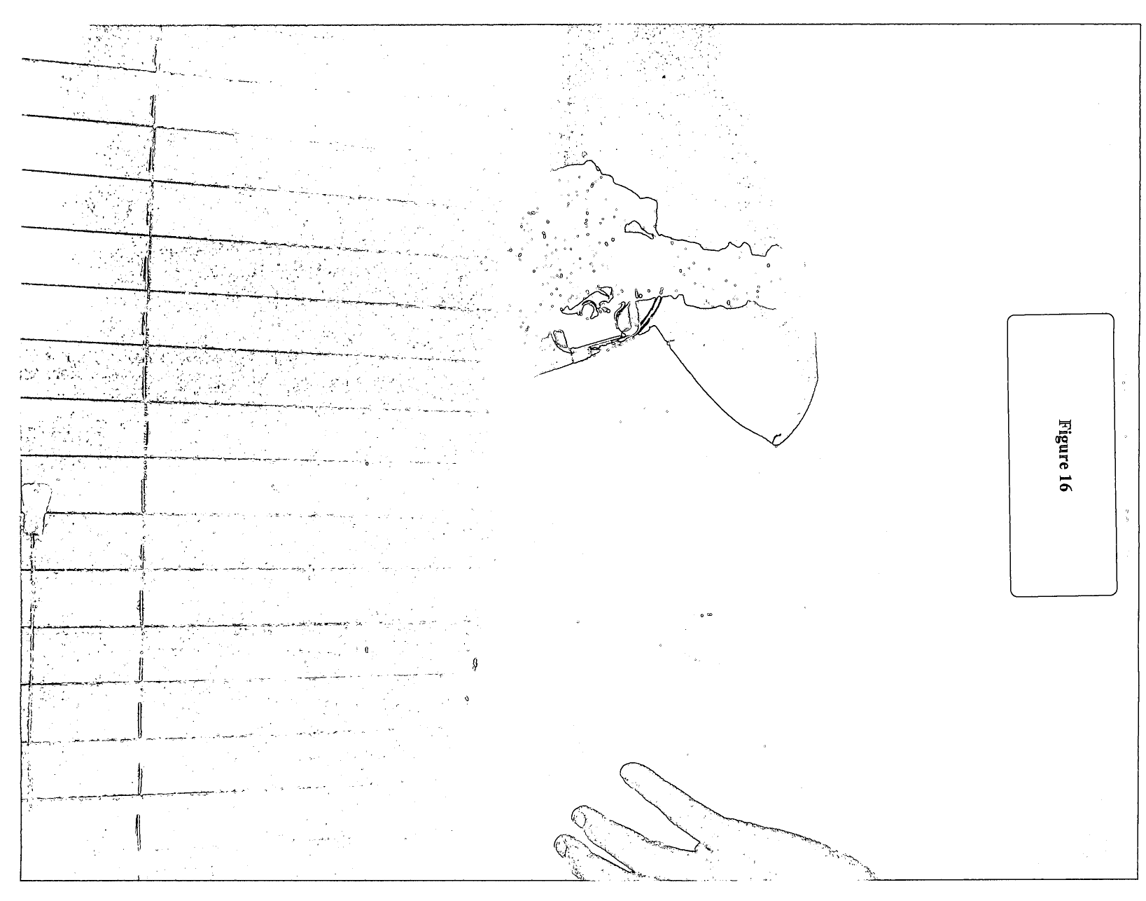

Alternative embodiments may be created by varying the single leg strap 10 of the invention. The single leg strap 10 and/or its covering may be of varying width, materials, colors, and designs. For example, the single leg strap 10 may be attached to other fabrics such as cotton, denim, polyester, faux fur FIG. 14, real fur, lace FIGS. 15 and 16, leather, mixed fabric, other natural or manmade fabric and the like in order to increase the flexibility for fashion. The strap may also be substituted with lycra or lycra blends or other elastomeric material or rubber or rubber-like material. The fabric employed may be of a variety of colors and patterns lending to the invention's functionality as a fashion accessory. The patterns may be intrinsic to the fabric such as plaid, polka dots, stripes, pictures, images, icons, logos and the like or the patterns may be directly applied onto the single leg strap 10 and/or the strap material may have a raised/sunken, molded or embroidered pattern. In addition, the fabric and/or the single leg strap 10 may be accented with sequins, rhinestones, beads, metal studs, gems and crystals of varying sizes, colors, and textures. A combination of fabrics may be employed such as cotton and lace SEE FIGS. 15 and 16, leather and denim, faux fur SEE FIG. 14 and leather, and the like. In addition to the fabric covering, the single leg strap 10 may be decorated with suitable ornamentation formed of plastic, metal, and the like for the hanging of beads, rhinestones, sequins, gems, crystals, chains and similar accessories. All of these variations may be combined in a number of ways, making the invention adaptable to any and all present and future fashion trends or materials. Further, one of ordinary skill in the art to which this invention belongs may employ these variations to other components or aspects of the invention.

In other alternate embodiments, the single leg strap 10 may consist of non-elastomeric material or fabric with an adjustable or non-adjustable clasp or the like closure/fastening device.

In various embodiments, the single leg straps 10 may be made completely of elastomeric material, or just a portion of the single leg strap 10, for example the additional support band 11, may be elastomeric material with the remainder consisting of non-elastomeric material or other fabric. These variations of elastomeric material, non-elastomeric material, clasps, and adjustable straps may be combined.

An alternate single leg strap 10 embodiment of the present invention may employ a D-ring or loop ring mechanism common to the ordinary brassiere strap or fashionable loop ring belting accessory for clothing and bags. The strap may consist of both adjustable D-rings and/or loop mechanism for adjustment and elastomeric portions. In addition, the adjustable strap embodiment may employ a clasp or closure device including but not limited to Velcro, lace up, plastic hooks common to those employed on swimsuit tops, hook and eye fasteners of varying sizes, snap-on fasteners in the click-in or magnetic variety, metal crimpers, side or center lock buckle fasteners, buttons, traditional tie closures and the like fastening devices known to one of ordinary skill in the art associated with fastening devices.

An alternate non-adjustable single leg strap embodiment of the present invention may employ a clasp or closure device including but not limited to Velcro, lace up, plastic hooks common to those employed on swimsuit tops, hook and eye fasteners of varying sizes, snap-on fasteners in the click-in or magnetic variety, metal crimpers, side or center lock buckle fasteners, D-ring or loop ring closure mechanism, buttons, traditional tie closures and the like fastening devices known to an ordinary person skilled in the art associated with fastening devices.

These combinations of clasps, adjustment devices, portions of straps made of elastomer or the entire strap made from elastomer, covered, decorated, raised, molded, various colors and patterns, may be varied and combined in any number of ways. Similarly, one of ordinary skill in the art to which this invention belongs will employ these variations in various embodiments to other components and aspects of the invention.

Other alternate embodiments may be created by varying the material of the pocket-like support area 40 formed by the support 15 and the electronic device straps 25, 30, and 35 of the invention.

In one such embodiment, the support 15, as illustrated in the preferred embodiment of FIG. 1, may be made of other material such as a number of natural and synthetic materials of varying sizes and shapes. This material could be made of silver, bronze, gold, or other suitable metal. Alternatively, this material may be made of wood, plastic, rubber, or a semi-hard material or other appropriate material that one of ordinary skill in the art to which this invention belongs would employ.

Alternatively, the support 15, as illustrated in FIG. 1, may have a variety of shapes such as a rectangle, square, triangle, pentagon, octagon, or other polygonal or freeform shapes. Also, the support 15 may be uncovered or covered by fabric, painted, or accented by other materials or other suitable surface ornamentation. For example, the fabric covering may also be functional with the metal for use in hot climates/weather because of its propensity to heat up and burn the skin or for rubber which may cause abrasion to the skin. Also, one of ordinary skill in the art to which this invention belongs will understand that the support 15 in all its various shapes as described herein may be smaller or larger in its dimensions yet retain its functionality. One of ordinary skill in the art to which this invention belongs will appreciate that the support 15 need not necessarily be round in its cross section either. The support 15 might be made of square or ovoid material and could twist creating an attractive yet functional component.

In another alternate embodiment, the support 15 may be substituted with a solid plate (rather than a ring) with slots, holes or other means for attaching straps as known to one of ordinary skill in the art associated with attaching straps. In this embodiment, one side of the would have a surface against which the small electronic device 45 may rest. The surface facing the leg might be contoured and/or might contain a ridge along its edge. The ridge would be raised on the side of the facing the leg, increasing the stability of the device 45 and further prevent slippage. The ridge might preferably be rounded about ¼ inch in diameter and protrude only from the surface on the leg side of the flat component. This surface area may be left uncovered or covered with fabric or other surface ornamentations as would be employed by one of ordinary skill in the art to which this invention belongs. The surface facing the leg might contain a variety of raised and lowered areas to increase friction with the leg to maintain stability and reduce slippage.

The alternate plate embodiment of the support 15 of the present invention referred to in the preceding paragraph may be made of a suitable plastic, metal or other material that one of ordinary skill in the arts would employ. The material can be painted, decorated and/or accented with surface ornamentations such as sequins, rhinestones, crystals, gems, etc., covered with decorative fabric, or covered with fashionable patches, badges, emblems, logos, or other modes of fashion branding/labeling. In this embodiment, the material on the support 15 may be transparent or opaque, may take on any suitable polygonal or freeform shapes, and be varied in size yet retain its functionality. The plate can also have portions cut out from the center area making it more “ring like” and/or allowing an open area for a portion of the small electronic device to “seat itself.”

In another alternate embodiment, the support 15 may be made of semi-hard material, rubber or rubber-like material, or material suitable for the injection molding process known to one of ordinary skill in the art. In addition, the solid plate variation mentioned above may be combined with the hard ring 15 or other polygonal and freeform shapes which may be made of metal, wood, plastic, rubber, or other semi-hard material. In this combination, the hard ring 15 would be placed and attached against the plate such that a one side of the hard ring 15 is in contact with one side of the plate and the other side of the hard ring 15 would be in contact with the leg. This arrangement would provide additional friction with the leg of the wearer and increase the stability of the small electronic device 45.

In yet another embodiment, a pocket as a means for securing/carrying I.D.'s, credit cards, business cards, dollar bills etc. may be attached to the invention either between the back of the small electronic device 45 and the support 15 or inserted between the front of the small electronic device 45 and the supporting pocket area 40. The pocket would be made from thin slices/swatches of fabric, plastic or other suitable material cut in an adequate shape and size to accommodate I.D.'s, credit cards, business cards, dollar bills etc. known to one of ordinary skill in the art. Depending on placement (either in front or in back of the small electronic device) one of ordinary skill in the arts would employ reasonable attachment to either the support 15 or plate or the additional support band 11. More than one pocket may be created by the additional pieces of material. Thus, to make three pockets, four swatches of fabric might be employed, layered on top of each other.

In an alternate embodiment a small pocket might be attached to the single leg strap 10. In another alternate embodiment, the three electronic device straps 25, 30, and 35 which comprise the remainder of the pocket-like area 40 may be made of various materials and be of varying width, colors, and designs. The three electronic device straps 25, 30, and 35 may be made of only elastic or other elastomeric material, a combination of elastic and fabric, rubber or rubber-like material, or other stretch or flexible material. For example, elastic straps may be attached to other fabrics such as cotton, denim, polyester, faux fur SEE FIG. 14, real fur, lace SEE FIGS. 15 and 16, leather, mixed fabric, other natural or manmade fabric and the like in order to increase the flexibility for fashion. The straps may also be substituted with lycra or lycra blends or other elastomeric material or rubber or rubber-like material. The fabric employed may be of a variety of colors and patterns lending to the invention's functionality as a fashion accessory. The patterns may be intrinsic to the fabric such as plaid, polka dots, stripes, pictures, images, icons, logos and the like or the patterns may be directly applied onto the strap material and/or the strap material may have a raised/sunken, molded or embroidered pattern. In addition, the fabric and/or the elastic straps may be accented with sequins, rhinestones, beads, metal studs, gems and crystals of varying sizes, colors, and textures. A combination of fabrics may be employed such as cotton and lace SEE FIGS. 15 and 16, leather and denim, faux fur SEE FIG. 14 and leather, and the like. In addition to the fabric covering, the straps may be decorated with suitable ornamentation formed of plastic, metal, and the like for the hanging of beads, rhinestones, sequins, gems, crystals, chains and similar accessories. All of these variations may be combined in a number of ways, making the invention adaptable to any and all present and future fashion trends.

In another alternate embodiment, the three electronic device straps 25, 30, and 35 may be varied in number and width/thickness. Instead of employing three electronic device straps 25, 30, and 35, four or more straps of varying sizes (width/thickness) or two or less straps of varying sizes (width/thickness). The arrangement of these straps may also be varied, departing from the two diagonal and one vertical strap orientation of the preferred embodiment of the present invention.

In an alternate embodiment, the three electronic device straps 25, 30, and 35 may be substituted by one piece of material to form a completely enclosed pouch or pocket rather than the harness design exemplified in the preferred embodiment SEE FIG. 1. The pocket or pouch would be open at the top to allow for insertion and removal of the small electronic device 45. Therefore, instead of having a vertical strap 25 combined with two other straps of varying orientation 30 and 35 to form part of the pocket like area 40, this embodiment would employ one continuous strap or fabric or other suitable material covering the hard ring 15 or other support material. The fabrics employed may include, but are not limited to cotton, denim, polyester, faux fur SEE FIG. 14, real fur, lace SEE FIGS. 15 and 16, leather, mixed fabric, lycra, or lycra blends and other natural or manmade fabrics. Alternatively, the pouch or holster may be made from semi-hard or flexible plastic, rubber or rubber-like materials, or a semi-fluid material suitable for injection molding technology. The pouch may be supported by a hard ring 15 or other support material and attached to the single leg strap 10 of the present invention. In this embodiment, the small electronic device would fit securely into the pouch, facilitating easy insertion, removal, and carrying.

In an alternate embodiment, the three electronic device straps 25, 30, and 35 and the additional support band 11 may be substituted by one piece of material to form a completely enclosed pouch or pocket rather than the harness design exemplified in the preferred embodiment SEE FIG. 1. The pocket or pouch would be open at the top to allow for easy insertion and removal of the small electronic device 45. Therefore, instead of having a vertical electronic device strap 25 combined with two appropriately angled electronic device straps 30, 35 and the additional support band 11 to form part of the pocket like area, this embodiment would employ one continuous strap or fabric or other suitable material covering the hard ring 15 or other support material. The fabrics employed may include, but are not limited to cotton, denim, polyester, faux fur SEE FIG. 14, real fur, lace SEE FIGS. 15 and 16, leather, mixed fabric, lycra, or lycra blends and other natural or manmade fabrics. Alternatively, the pouch may be made from semi-hard or flexible plastic, rubber or rubber-like materials, or a semi-fluid material suitable for injection molding technology. The pouch may be supported by a hard ring 15 or other support material and attached to the single strap component of the present invention. In this embodiment, the small electronic device 45 would fit securely into the pouch, facilitating easy insertion, removal, and carrying.

In another alternate embodiment, the present invention may be comprised of fewer or more than three components. Components can be combined or added and manufactured by one of ordinary skill in the art of injection molding, casting, vacuum molding and the like processes, technologies, and designs.

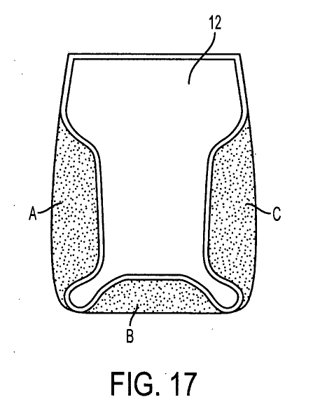

In another embodiment of the present invention as illustrated in FIG. 17, the three electronic device straps 25, 30, and 35 and the additional support band 11 may be substituted by a rigid plastic pocket 12 attached to the single leg strap component 10 by a fixed or removable fastener known to one of ordinary skill in the art. The small electronic device would drop in from the top and fit somewhat snugly to be held securely in place. The rigid plastic pocket 12 has a flat surface that lies against the leg with rounded edges that protrude away from the leg of the wearer. The flat surface and the rounded edges may vary in length and height to accommodate the size of the small electronic device 45. The rigid pocket 12 may also be made of a variety of materials such as leather, metal or other material that one of ordinary skill in the art would employ. FIG. 17 illustrates the detail of the edges A, B, and C that arise from the plate, project outwards and curve over the edge of the small electronic device. It is understood that this rigid plastic pocket 12 could have shorter and smaller edges and corresponding smaller rounded portions overlapping the small electronic device 45. It is also understood that in embodiments where the edges are shorter an elastic strap or clip device over the upper portion or top of the small electronic device 45 may be required.

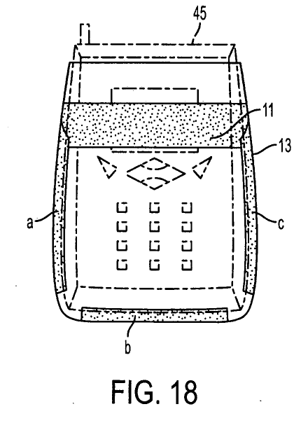

In an alternative embodiment one or more straps would be utilized as described in preceding embodiments combined with a rigid plastic plate with edge extensions 13. FIG. 18 illustrates, the rigid plastic plate with edge extensions 13 attached to the additional support band 11 of the single leg strap 10 by a fixed or removable fastener known to one of ordinary skill in the arts. Unlike the rigid plastic pocket 12 described above the edges of the rigid plastic plate with edge extensions a, b, and c are smaller as shown in FIG. 18 and would protrude only a few millimeters from the plate that they arise from and not curl over the small electronic device. The rigid plastic plate with edge extensions 13 may also be made of a variety of materials such as leather, metal or other material that one of ordinary skill in the arts would employ.

In an alternate embodiment of the present invention the electronic device straps 25, 30, and 35 may be substituted by a clip that would be an integrated removable fastening device on the back of the small electronic device 45. In this embodiment the clip or removable fastener known to one of ordinary skill in the arts would be easily attached or detached from the complementary portion of the clip that is attached to the support 15 as described in embodiments above.

Although the preferred embodiment is the “garter” type device to be worn on the leg or thigh SEE FIG. 1, the invention is adaptable to other users and uses. The “garter”design may also be worn on the leg or thigh of a man. In addition, the invention is adaptable to various fashion modes and trends. For example, the present invention may lend itself to the displaying of sports logos, badges, patches, and emblems whether embroidered, stitched, or attached by other suitable means. The present invention is adaptable to all modes of fashion for the attachment of fashion labels, monikers, emblems and brands.

What is claimed is:

1. An electronic device holder for attachment to the leg or thigh comprising:
A leg strap composed partially or entirely of elastomeric material to accommodate a variety of leg widths; and
A hard or semi-hard support attaching to the leg strap, with or without a tensioning device such as a D-ring, to form the back surface of the space that supports the small electronic device and further secures the electronic device to the user's leg or thigh; and
Electronic device straps attached to the hard or semi-hard support composed partially or entirely of elastomeric material, oriented to secure the electronic device over its bottom and sides to the user's leg or thigh.

2. The electronic device holder of claim 1 further comprising a leg strap covered in decorative ornaments, decorations, appliques, raised/sunken, molded or embroidered patterns or other decorative fabrics, either natural or manmade, containing patterned or non-patterned coverings or any such patterns that may be applied to the strap material for functionality as a fashion accessory.

3. The electronic device holder of claim 1 further comprising a leg strap that is composed of two parts, at least one portion containing a Velcro, clasp, lace-up, button or tie-up closure mechanism.

4. An electronic device holder of claim 1 further comprising a hard or semi-hard support composed of any metal or metal alloy, wood, plastic, rubber, or another semi-hard material or a combination of same.

5. An electronic device holder of claim 1 further comprising a hard or semi-hard support of any shape, including but not limited to polygonal or freeform shapes.

6. An electronic device holder of claim 1 further comprising a hard or semi-hard support composed of a plate which may be transparent, opaque, painted, decorated and/or otherwise accented, fabric covered, and/or utilizing surface ornamentations with a slot, hole or other means of attaching the straps, with one side positioned to accommodate the electronic device and the opposing side of said plate containing raised or lowered areas to increase friction with the leg to maintain stability and reduce slippage.

7. An electronic device holder of claim 6 further comprising a hard or semi-hard support composed of a plate with holes or cut out portions, making it more “ring like” and thereby increasing friction against the leg or thigh.

8. An electronic device holder of claim 1, in which one or more swatches of fabric, plastic or other suitable material cut in adequate shapes and sizes to accommodate I.D.'s, credit cards, business cards, and/or dollar bills, is attached to the electronic device holder and positioned either in front or in back of the small electronic device.
